(19) United States
(12) Patent Application Publication
(10) Pub. No.: US 2021/0388261 A1
(43) Pub. Date: Dec. 16, 2021

(54) PEROVSKITE LIGHTING SYSTEMS

(71) Applicant: Wake Forest University, Winston-Salem, NC (US)

(72) Inventors: David Carroll, Winston-Salem, NC (US); Junwei Xu, Winston-Salem, NC (US)

(21) Appl. No.: 17/285,762

(22) PCT Filed: Oct. 16, 2019
(86) PCT No.: PCT/US2019/056556

§ 371 Date: Apr. 15, 2021

Related U.S. Application Data
(60) Provisional application No. 62/746,369, filed on Oct. 16, 2018.

(51) Int. Cl. C09K 11/66; C01G 21/00

(52) U.S. Cl. CPC C09K 11/665; H01L 51/502; C01G 21/006

(57) ABSTRACT

In one aspect, composite nanoparticles are provided. In some embodiments, a composite nanoparticle comprises a host matrix comprising A₄BX_{6-Z}Y_{Z} and ABX_{3-P}Y_{P} inclusions dispersed within the host matrix of the composite nanoparticle, wherein A is an alkali metal, B is an element selected from the group consisting of transition metals, Group IVA elements and rare earth elements and X and Y are independently selected from Group VIIA elements, 0≤z≤6, and 0≤p<3.

### RELATED APPLICATION DATA

The present invention claims priority pursuant to 35 U.S.C. § 119(e) to U.S. Provisional Patent Application Ser. No. 62/746,369 filed Oct. 16, 2018 which is incorporated herein by reference in its entirety.

### FIELD

The present invention relates to composite perovskite materials and, in particular, to composite perovskite materials for application in various lighting systems.

### BACKGROUND

Lead halide perovskites, as direct bandgap semiconductors, show very low efficiency of light emission at room temperature in bulk crystals, dominated by carrier trapping. Measured values of the exciton binding energy in lead halide perovskite, typical CsPbBr₃, range from 19 meV to about 60 meV. At room temperature, such shallow excitons are ionized to free carriers in a very short time, so energy transport occurs mainly by free and/or shallow-trapped carriers, and radiative recombination should obey second-order kinetics for the most part. However, low-dimensional lead halide perovskites become promising candidates to beat the second-order kinetics bottleneck, and have been researched intensively ever since the near unity of photoluminescence quantum yield were first reported in 2012. This is because the nanometer scale spatial confinement of electrons and holes promotes the probability of geminate recombination, which consequently leads to the picosecond decay and enhanced absorption strength.

Motivated by the merits of nanostructured halide perovskites, many approaches to low-dimensional perovskites have been studied in various synthesis methods including 3D structure (nanoparticles, nanowires, and nanoplates) and layered structure (quasi-2D). In general, organic surfactants or organic cations are required to either chemically terminate the crystal growth or create the mechanical exfolication between perovskite sheets. Although the ligand-assisted methods benefit good reproducibility and high yield, the organic additives attached the crystal surfaces and significantly hindered the charge transport due to extremely low conductivity of the organic compounds. Meanwhile, the small molecule surfactants were blamed for one of the critical reasons for the poor stability of halide perovskite films when it loses the support of surrounding solution. In the past few years, great efforts were made to understand and stabilize the low dimensional lead halide perovskites towards high resistivity to moisture and heat, however, the robustness of the perovskite LEDs is still a challenge.

### SUMMARY

In view of these disadvantages, composite perovskite compositions are described herein exhibiting desirable lighting characteristics and robustness. In one aspect, composite nanoparticles are provided. In some embodiments, a composite nanoparticle comprises a host matrix comprising A₄BX_{6-z}Y_{z}, and ABX₃₋ₚYₚ inclusions dispersed within the host matrix of the composite nanoparticle, wherein A is an alkali metal, B is an element selected from the group consisting of transition metals, Group IVA elements and rare earth elements and X and Y are independently selected from Group VIIA elements, 0≤z≤6, and 0≤p<3. When z equals 6, X assumes the subscript of zero, thereby making the formula A₄BY₆. In being dispersed within the host matrix of A₄BX_{6-z}Y_{z}, the ABX₃₋ₚYₚ inclusions reside in the bulk of the host matrix. In some embodiments, for example, the ABX₃₋ₚYₚ inclusions are not present on surfaces of the host matrix.

The ABX₃₋ₚYₚ inclusions can be photoluminescent and/or electroluminescent. The ABX₃₋ₚYₚ inclusions, for example, can emit light in the visible region of the electromagnetic spectrum. In some embodiments, composition of the ABX₃₋ₚYₚ inclusions can be varied to emit red, green or blue light. The ABX₃₋ₚYₚ inclusions can have peak emission from 500-550 nm, 600-700 nm or 400-500 nm. The emission can have a full width half maximum of 20 nm or less, in some embodiments. The ABX₃₋ₚYₚ inclusions can form a Type I band offset with the A₄BX_{6-z}Y_{z} host, in some embodiments. In non-limiting embodiments, the host matrix comprises Cs₄PbBr₆ and inclusions are CsPbBr₃ and/or CsPbI₃. In other embodiments, the host matrix comprises Cs₄PbBr₆ and inclusions are CsPbI₂Br. As described further herein, the host matrix comprising A₄BX_{6-z}Y_{z} and/or ABX₃₋ₚYₚ inclusions can be crystalline.

Additionally, a capping layer can reside between the ABX₃₋ₚYₚ inclusions and host matrix. The capping layer can have a composition different form the ABX₃₋ₚYₚ inclusions and the A₄BX_{6-z}Y_{z} host matrix. In some embodiments, the capping layer exhibits a Br gradient. Moreover, the capping layer can partially or fully surround an ABX₃₋ₚYₚ inclusion and/or have thickness less than 5 nm.

In another aspect, thin perovskite films are provided. In some embodiments, a thin film comprises a continuous host matrix comprising A₄BX_{6-z}Y_{z}, and ABX₃₋ₚYₚ inclusions dispersed within the host matrix, wherein A is an alkali metal, B is an element selected from the group consisting of transition metals, Group IVA elements and rare earth elements and X and Y are independently selected from Group VIIA elements, 0≤z≤6, and 0≤p<3. In being dispersed within the host matrix, the ABX₃₋ₚYₚ inclusions reside in the bulk of the host matrix. In some embodiments, for example, the ABX₃₋ₚYₚ inclusions are not present on surfaces of the host matrix or surfaces of the thin film.

The ABX₃₋ₚYₚ inclusions can be photoluminescent and/or electroluminescent. The ABX₃₋ₚYₚ inclusions, for example, can emit light in the visible region of the electromagnetic spectrum. In some embodiments, composition of the ABX₃₋ₚYₚ inclusions can be varied to emit red, green or blue light. The ABX₃₋ₚYₚ inclusions can have peak emission from 500-550 nm, 600-700 nm or 400-500 nm. The emission can have a full width half maximum of 20 nm or less, in some embodiments. The ABX₃₋ₚYₚ inclusions can form a Type I band offset with the A₄BX_{6-z}Y_{z} host, in some embodiments. In non-limiting embodiments, the host matrix comprises Cs₄PbBr₆ and inclusions are CsPbBr₃ and/or CsPbI₃. In other embodiments, the host matrix comprises Cs₄PbBr₆ and inclusions are CsPbI₂Br. As described further herein, the host matrix comprising A₄BX_{6-z}Y_{z} and/or ABX₃₋ₚYₚ inclusions can be crystalline.

Additionally, a capping layer can reside between the ABX₃₋ₚYₚ inclusions and host matrix. The capping layer can have a composition different form the ABX₃₋ₚYₚ inclusions and the A₄BX_{6-z}Y_{z} host matrix. In some embodiments, the capping layer exhibits a Br gradient. Moreover, the capping layer can partially or fully surround an ABX₃₋ₚYₚ inclusion and/or have thickness less than 5 nm.

The thin perovskite film can have any desired thickness. In some embodiments, thickness of the thin film is at least 100 nm. The thin perovskite film, for example can have thickness of 100 nm to 1 μm.

In a further aspect, electroluminescent devices are described herein. An electroluminescent device comprises a first electrode and a second electrode and a light emitting layer positioned between the first and second electrodes, the light emitting layer comprising a continuous host matrix comprising A₄BX_{6-z}Y_{z}, and ABX₃₋ₚYₚ inclusions dispersed within the host matrix, wherein A is an alkali metal, B is an element selected from the group consisting of transition metals, Group IVA elements and rare earth elements and X and Y are independently selected from Group VIIA elements, 0≤z≤6, and 0≤p<3. In being dispersed within the host matrix, the ABX₃₋ₚYₚ inclusions reside in the bulk of the host matrix. In some embodiments, for example, the ABX₃₋ₚYₚ inclusions are not present on surfaces of the host matrix or surfaces of the light emitting layer.

The ABX₃₋ₚYₚ inclusions are electroluminescent. The ABX₃₋ₚYₚ inclusions, for example, can emit light in the visible region of the electromagnetic spectrum. In some embodiments, composition of the ABX₃₋ₚYₚ inclusions can be varied to emit red, green or blue light. The ABX₃₋ₚYₚ inclusions can have peak emission from 500-550 nm, 600-700 nm or 400-500 nm. The emission can have a full width half maximum of 20 nm or less, in some embodiments. The ABX₃₋ₚYₚ inclusions can form a Type I band offset with the A₄BX_{6-z}Y_{z} host matrix in some embodiments. In non-limiting embodiments, the host matrix comprises Cs₄PbBr₆ and inclusions are CsPbBr₃ and/or CsPbI₃. In other embodiments, the host matrix comprises Cs₄PbBr₆ and inclusions are CsPbI₂Br. As described further herein, the host matrix comprising A₄BX_{6-z}Y_{z} and/or ABX₃₋ₚYₚ inclusions can be crystalline. The presence of a host matrix comprising A₄BX_{6-z}Y_{z} can sufficiently passivate the light emitting ABX₃₋ₚYₚ inclusions, thereby precluding the use or presence of organic ligands, such as CH₃NH₃Br (MABr).

Additionally, a capping layer can reside between the ABX₃₋ₚYₚ inclusions and host matrix. The capping layer can have a composition different form the ABX₃₋ₚYₚ inclusions and the A₄BX_{6-z}Y_{z} host matrix. In some embodiments, the capping layer exhibits a Br gradient. Moreover, the capping layer can partially or fully surround an ABX₃₋ₚYₚ inclusion and/or have thickness less than 5 nm.

The light emitting layer can have any desired thickness. In some embodiments, thickness of the thin film is at least 100 nm. The thin perovskite film, for example can have thickness of 100 nm to 1 um.

The first and/or second electrode can be radiation transmissive, thereby enabling top emitting devices. In some embodiments, the radiation transmissive first and/or second electrodes are metal or alloy. In other embodiments, a radiation transmissive electrode may be a conductive metal oxide. Radiation transmissive conducting oxides can include one or more of indium tin oxide (ITO), gallium indium tin oxide (GITO), aluminum tin oxide (ATO) and zinc indium tin oxide (ZITO). In some embodiments, a radiation transmissive first and/or second electrode is formed of a radiation transmissive polymeric material such as polyanaline (PANT) and its chemical relatives or 3,4-polyethylenedioxythiophene (PEDOT). Further, a radiation transmissive first and/or second electrode can be formed of a carbon nanotube layer having a thickness operable to at least partially pass visible electromagnetic radiation. An additional radiation transmissive material can comprise a nanoparticle phase dispersed in a polymeric phase. The electroluminescent device may be connected to a direct current source, thereby functioning as a light emitting diode. In other embodiments, the electroluminescent device may be connected to an alternating current source.

In some embodiments, one or more hole transport layers (HTL) are positioned between the anode and perovskite light emitting layer(s). Similarly, one or more electron transport layers (ETL) can be positioned between the cathode and perovskite light matting layer(s). Specific compositional identity of HTLs and ETLs can be dependent upon the electronic structure of the organic-inorganic perovskite nanocrystal layer(s) and electrode composition. In some embodiments, for example, a HTL comprises poly[N,N′-bis(4-butylphenyl)-N,N′-bis(phenyl)-benzidine] (poly-TPD), poly(9-vinylcatbazole) (PVK), 3,3′-di(9H-carbazol-9-yl)-1,1′-biphenyl (CBP), or PEDOT:PSS. In some embodiments, an ETL comprises 2,2′,2″-(1,3,5-benzinetriyl)-tris(1-phenyl-1-H-benzimidazole) (TPBi) or phenyl-dipyrenylphosphine oxide (POPy₂).

In some embodiments, the electroluminescent device further comprises a current injection gate positioned between the first electrode and the light emitting layer or between the second electrode and the light emitting layer, wherein the current injection gate comprises a semiconductor layer of electronic structure restricting injected current flow from the first or second electrode through the semiconductor layer as a function of alternating current voltage frequency applied to the first and second electrodes. In such embodiments, the electroluminescent device may be connected to an alternating current source.

Semiconducting materials demonstrating frequency dependent restriction of injected current from the first or second electrode can serve as the current injection gate in the electroluminescent device architecture. Suitable gate semiconductor materials can comprise inorganic semiconductors and organic semiconductors. For example, in some embodiments, inorganic gate semiconductors comprise transition metal oxides, including titanium oxide. In some embodiments, inorganic gate semiconductors are selected from Tables I and II.

TABLE I
Inorganic Gate Semiconductors

| | |
|---|---|
| Silicon | Si |
| Germanium | Ge |
| Gray tin, α-Sn | Sn |
| Silicon carbide, 3C—SiC | SiC |
| Silicon carbide, 4H—SiC | SiC |
| Silicon carbide, 6H—SiC | SiC |
| Sulfur, α-S | S₈ |
| Gray selenium | Se |
| Tellurium | Te |
| Boron nitride, cubic | BN |
| Boron nitride, hexagonal | BN |
| Boron nitride, nanotube | BN |
| Boron phosphide | BP |
| Boron arsenide | BAs |
| Boron arsenide | B₁₂As₂ |
| Aluminium nitride | AlN |
| Aluminium phosphide | AlP |
| Aluminium arsenide | AlAs |
| Aluminium antimonide | AlSb |
| Gallium nitride | GaN |
| Gallium phosphide | GaP |
| Gallium arsenide | GaAs |
| Gallium antimonide | GaSb |
| Indium nitride | InN |
| Indium phosphide | InP |
| Indium arsenide | InAs |
| Indium antimonide | InSb |
| Cadmium selenide | CdSe |
| Cadmium sulfide | CdS |
| Cadmium telluride | CdTe |
| Zinc oxide | ZnO |
| Zinc selenide | ZnSe |
| Zinc sulfide | ZnS |
| Zinc telluride | ZnTe |
| Cuprous chloride | CuCl |
| Copper sulfide | CU₂S |
| Lead selenide | PbSe |
| Lead(II) sulfide | PbS |
| Lead telluride | PbTe |
| Tin sulfide | SnS |
| Tin sulfide | SnS₂ |
| Tin telluride | SnTe |
| Lead tin telluride | PbSnTe |
| Thallium tin telluride | Tl₂SnTe₅ |
| Thallium germanium telluride | Tl₂GeTe₅ |
| Bismuth telluride | Bi₂Te₃ |
| Cadmium phosphide | Cd₃P₂ |
| Cadmium arsenide | Cd₃As₂ |
| Cadmium antimonide | Cd₃Sb₂ |
| Zinc phosphide | Zn₃P₂ |
| Zinc arsenide | Zn₃As₂ |
| Zinc antimonide | Zn₃Sb₂ |
| Titanium dioxide, anatase | TiO₂ |
| Titanium dioxide, rutile | TiO₂ |
| Titanium dioxide, brookite | TiO₂ |
| Copper(I) oxide | Cu₂O |
| Copper(II) oxide | CuO |
| Uranium dioxide | UO₂ |
| Uranium trioxide | UO₃ |
| Bismuth trioxide | Bi₂O₃ |
| Tin dioxide | SnO₂ |
| Barium titanate | BaTiO₃ |
| Strontium titanate | SrTiO₃ |
| Lithium niobate | LiNbO₃ |
| Lanthanum copper oxide | La₂CuO₄ |
| Lead(II) iodide | PbI₂ |
| Molybdenum disulfide | MoS₂ |
| Gallium selenide | GaSe |
| Tin sulfide | SnS |
| Bismuth sulfide | Bi₂S₃ |
| Gallium manganese arsenide | GaMnAs |
| Indium manganese arsenide | InMnAs |
| Cadmium manganese telluride | CdMnTe |
| Lead manganese telluride | PbMnTe |
| Lanthanum calcium manganate | La_{0.7}Ca_{0.3}MnO₃ |
| Iron(II) oxide | FeO |
| Nickel(II) oxide | NiO |
| Europium(II) oxide | EuO |
| Europium(II) sulfide | EuS |
| Chromium(III) bromide | CrBr₃ |
| Copper indium selenide, CIS | CuInSe₂ |
| Silver gallium sulfide | AgGaS₂ |
| Zinc silicon phosphide | ZnSiP₂ |
| Arsenic sulfide | As₂S₃ |
| Platinum silicide | PtSi |
| Bismuth(III) iodide | BiI₃ |
| Mercury(II) iodide | HgI₂ |
| Thallium(I) bromide | TlBr |
| Silver sulfide | Ag₂S |
| Iron disulfide | FeS₂ |
| Copper zinc tin sulfide, CZTS | Cu₂ZnSnS₄ |

TABLE II
Inorganic Gate Semiconductors

| | |
|---|---|
| Silicon-germanium | Si₁₋ₓGeₓ |
| Aluminium gallium arsenide | AlₓGa₁₋ₓAs |
| Indium gallium arsenide | InₓGa₁₋ₓAs |
| Indium gallium phosphide | InₓGa₁₋ₓP |
| Aluminium indium arsenide | AlₓIn₁₋ₓAs |
| Aluminium indium antimonide | AlₓIn₁₋ₓSb |
| Gallium arsenide nitride | GaAsN |
| Gallium arsenide phosphide | GaAsP |
| Gallium arsenide antimonide | GaAsSb |
| Aluminium gallium nitride | AlGaN |
| Aluminium gallium phosphide | AlGaP |
| Indium gallium nitride | InGaN |
| Indium arsenide antimonide | InAsSb |
| Indium gallium antimonide | InGaSb |
| Aluminium gallium indium phosphide | AlGaInP |
| Aluminium gallium arsenide phosphide | AlGaAsP |
| Indium gallium arsenide phosphide | InGaAsP |
| Indium gallium arsenide antimonide | InGaAsSb |
| Indium arsenide antimonide phosphide | InAsSbP |
| Aluminium indium arsenide phosphide | AlInAsP |
| Aluminium gallium arsenide nitride | AlGaAsN |
| Indium gallium arsenide nitride | InGaAsN |
| Indium aluminium arsenide nitride | InAlAsN |
| Gallium arsenide antimonide nitride | GaAsSbN |
| Gallium indium nitride arsenide antimonide | GaInNAsSb |
| Gallium indium arsenide antimonide phosphide | GaInAsSbP |
| Cadmium zinc telluride, CZT | CdZnTe |
| Mercury cadmium telluride | HgCdTe |
| Mercury zinc telluride | HgZnTe |
| Mercury zinc selenide | HgZnSe |
| Copper indium gallium selenide, CIGS | Cu(In,Ga)Se₂ |

Moreover, organic gate semiconductors can comprise small molecule semiconductors including acene and/or acene derivatives such as anthracene, tetracene, pentacene, hexacene, heptacene or rubrene. In some embodiments, small molecule gate semiconductor is selected from Table III.

TABLE III
Small Molecule Gate Semiconductors

2,7-alkyl[1]benzothieno[3,2-b][1]benzothiophene (C8-BTBT)
2,9-alkyl-dinaphtho[2,3-b:2′,3′-f]thieno[3,2-b]thiophene (C 10 -DNTT)
N,N-1 H,1H-perfluorobutyldicyanoperylene-carboxydiimide (PDIF-CN₂)
Sexithiophene (6T)
poly[9,9′dioctyl-fluorene-co-bithiophene] (F8T2)
polytriarylamine (PTAA)
poly-2,5-thienylene vinylene (PVT)
α,ω-dihexylquinquethiophene (DH-5T)
α,ω-dihexylsexithiophene (DH-6T)
perfluorocopperphthalocyanine (FPcCu)
3′,4′-dibutyl-5,5″-bis(dicyanomethylene)-5,5″-dihydro-
2,2′:5′,-2″-terthiophene (QM3T)
α,ω-diperfluorohexyloligothiophene (DFH-nT)
2,7-[bis(5-perfluorohexylcarbonylthien-2-y1)]-4H-cyclopenta-
[2,1-b:3,4-b′]-dithiophen-4-one (DFHCO-4TCO)
Poly[bisbenzimidazobenzophenanthroline] (BBB)
α,ω-diperfluorophenylquaterthiophene (FTTTTF)
dicyanoperylene-bis[dicarboximide] (DPI-CN)
naphthalene tetracarboxylic diimide (NTCDI)
Tetracene
Anthracene
Tetrathiafulvalene (TTF)
Poly(3-alkythiophene)
Dithiotetrathiafulvalene (DT-TTF)
Cyclohexylquaterthiophene (CH4T)

Additionally, organic gate semiconductor can comprise one or more conjugated polymeric materials including polyacetylene, polyacetylene derivatives, poly(9,9-di-octylfluorene-alt-benzothiadiazole) (F8BT), poly[2-methoxy-5-(2-ethylhexyloxy)-1,4-phenylenevinylene] [MEH-PPV], P3HT, poly(3,4-ethylenedioxythiophene) (PEDOT), PEDOT:PSS or mixtures thereof. In some embodiments, gate semiconductor is formed of carbon nanoparticles, such as those listed in Table IV.

TABLE IV
Carbon Nanoparticle Gate Semiconductors

Fullerene - C₆₀
(6,6)-phenyl-C₆₁butyric acid methyl ester (PC₆₁BM)
(6,6)-phenyl-C₇₁butyric acid methyl ester (PC₇₁BM)
(6,6)-phenyl-C₆₁methyl-hexanoate (PC₆₁HM)
(5,6)-fullerene-C₇₀
(6,6)-phenyl-C₇₁hexanoic acid methyl ester (PC₇₁HM)

Gate semiconductors can be intrinsic or doped. Further, suitable inorganic and/or organic gate semiconductors can demonstrate a bandgap of at least 2 eV or at least 3 eV. In some embodiments, gate semiconductor material has a bandgap of 2 to 4 eV or 2.5 to 3.5 eV.

A semiconductor layer of a current injection gate can have any thickness not inconsistent with the objectives of the present invention. In some embodiment, a gate semiconductor layer has a thickness selected from Table V.

```
TABLE V
Current Injection Gate Semiconductor Layer Thickness (nm)
  1-500
  5-100
10-75
15-50
20-40
```

In further embodiments, a current injection gate having frequency dependent behavior can be a composite formed of organic and inorganic components. For example, a current injection gate composite can comprise inorganic particles dispersed in a polymeric matrix. In some embodiments, one or more ceramic particles (e.g. metal carbides, metal oxides, metal carbonitrides, metal nitrides, metal oxynitrides and/or metal oxycarbonitrides) can be dispersed in a conjugated or semiconducting polymeric matrix to provide a current injection gate exhibiting a frequency dependent restriction of injected current from the first or second electrode. A current injection gate composite can employ up to about 90 wt % inorganic particles with the balance polymeric matrix. In some embodiments, a current injection gate comprises 15-75 wt. % inorganic particles with the balance polymeric matrix. Suitable inorganic particles and conjugated polymer for the current injection gate composite are described in this Section C. Inorganic particles for the composite current injection gate can have any average particle size not inconsistent with the objectives of the present invention. For example, in some embodiments, the inorganic particles are nanoparticles having an average size less than 1 μm. In some embodiments, the inorganic particles have an average size from 10 μm to 500 μm. Alternatively, the inorganic particles can have an average size greater than 1 μm. A current injection gate composite, in some embodiments, has a thickness selected from Table V.

An electroluminescent device may also be encapsulated in a hydrophobic of water resistant material, such as a polysiloxane or other elastomer. Moreover, electroluminescent devices described herein are flexible, in some embodiments. Additionally, electroluminescent devices described herein can exhibit lighting efficiencies of at least 100 lm/W or at least 200 lm/W and lifetimes in excess of 1,000 hours, 5,000 hours or 10,000 hours. In some embodiments, an electroluminescent device described herein has a lighting efficiency of 150-250 lm/W and/or a lifetime of 5,000-15,000 hours.

These and other embodiments are further described in the detailed description which follows.

### BRIEF DESCRIPTION OF THE DRAWINGS

FIG. 1a illustrates composite nanoparticles according to some embodiments wherein CsPbBr₃ nano-inclusions embedded Cs₄PbBr₆ matrix in a core-shell architecture.

FIG. 1b are transmission electron microscopy images (TEM) of the composite nanoparticles according to some embodiments.

FIG. 1c illustrates a Type I heterojunction between CsPbBr₃ inclusions in a Cs₄PbBr₆ host matrix according to some embodiments.

FIG. 1d provide photoluminescence spectrum and absorption coefficient of the CsPbBr₃—Cs₄PbBr₆ architecture according to some embodiments.

FIG. 1e optical clarity and photoluminescence of a perovskite film comprising CsPbBr₃ nano-inclusions embedded Cs₄PbBr₆ matrix according to some embodiments.

FIG. 1f is an atomic force microscopy (AFM) image of a perovskite film comprising CsPbBr₃ nano-inclusions embedded Cs₄PbBr₆ matrix according to some embodiments.

FIG. 1g illustrates a light emitting diode (LED) architecture employing a perovskite film comprising CsPbBr₃ nano-inclusions embedded Cs₄PbBr₆ matrix according to some embodiments.

FIG. 1h illustrates a band diagram for the LED architecture illustrated in FIG. 1g.

FIG. 1i illustrates top emission from the LED architecture of FIG. 1g according to some embodiments.

FIG. 2a illustrates electroluminescence spectra (EL) of LED devices based on CsPbBr₃ quantum dots and CsPbBr₃ nano-inclusions embedded Cs₄PbBr₆ matrix, respectively according to some embodiments.

FIG. 2b illustrates the dependence of the current density and luminance on the driving voltage in the devices based on CsPbBr₃ quantum dots and CsPbBr₃ nano-inclusions embedded Cs₄PbBr₆ matrix, respectively according to some embodiments.

FIG. 2c illustrates current efficiency and power efficiency as a function of current density for devices based on CsPbBr₃ quantum dots and CsPbBr₃ nano-inclusions embedded Cs₄PbBr₆ matrix, respectively according to some embodiments.

FIG. 2d brightness of the devices based on CsPbBr₃ quantum dots and CsPbBr₃ nano-inclusions embedded Cs₄PbBr₆ matrix, respectively according to some embodiments.

FIG. 2e illustrates current efficiency over time for devices based on CsPbBr₃ quantum dots and CsPbBr₃ nano-inclusions embedded Cs₄PbBr₆ matrix, respectively at a current density of 62.5 mA/cm².

FIG. 2f illustrates water resistant Cs₄PbBr₆ films with polydimethysulfoxide (PDMS) encapsulation according to some embodiments.

FIG. 2g illustrates transparency of CsPbBr₃—Cs₄PbBr₆ thin films before and after moisture aging.

FIG. 2h illustrates EL intensity and voltage of PDMS sealed CsPbBr₃—Cs₄PbBr₆ LEDs under water according to some embodiments.

FIG. 2i illustrates water resistance testing of LEDs described herein according to some embodiments.

FIG. 3a illustrates EL intensity of a CsPbBr₃—Cs₄PbBr₆ LED after post thermal treatment at different temperatures according to some embodiments.

FIG. 3b illustrates quantum yield of a CsPbBr₃—Cs₄PbBr₆ thin film after post thermal treatment according to some embodiments.

FIG. 3c illustrates cooling processes of a CsPbBr₃—Cs₄PbBr₆ thin film through metal and air under UV illumination according to some embodiments.

FIG. 3d is the PL spectrum of a CsPbBr₃—Cs₄PbBr₆ thin film during the heating process according to some embodiments.

FIG. 3e is the PL spectrum of a CsPbBr₃—Cs₄PbBr₆ thin film during the heating process according to some embodiments.

FIG. 4a provide brightness bending test results of a CsPbBr₃—Cs₄PbBr₆ LED, according to some embodiments.

FIG. 4b displays voltage variation at a constant current of 62.5 mA/cm² in the brightness bending test.

FIG. 4c is a dark field image of the Al-based CsPbBr₃—Cs₄PbBr₆ LED after 10,000 bends.

FIG. 4d illustrates cracks in the ITO/Al-based CsPbBr₃—Cs₄PbBr₆ LED after 10 bends.

FIG. 4e illustrates luminance and current variation as a function of LED bending angle according to some embodiments.

FIG. 4f illustrates EL spectra of the CsPbBr₃—Cs₄PbBr₆ LED during bending testing, according to some embodiments.

FIG. 4g is a bright optical image of four pixels in an 8×8 CsPbBr₃—Cs₄PbBr₆ LED matrix according to some embodiments.

FIG. 4h illustrates a flexible CsPbBr₃—Cs₄PbBr₆ LED matrix display according to some embodiments.

### DETAILED DESCRIPTION

Embodiments described herein can be understood more readily by reference to the following detailed description, examples and drawings. Elements, apparatus, and methods described herein, however, are not limited to the specific embodiments presented in the detailed description, examples and drawings. It should be recognized that these embodiments are merely illustrative of the principles of the present invention. Numerous modifications and adaptations will be readily apparent to those of skill in the art without departing from the spirit and scope of the invention.

### Example 1—Composite Peroskite Thin Film and LED

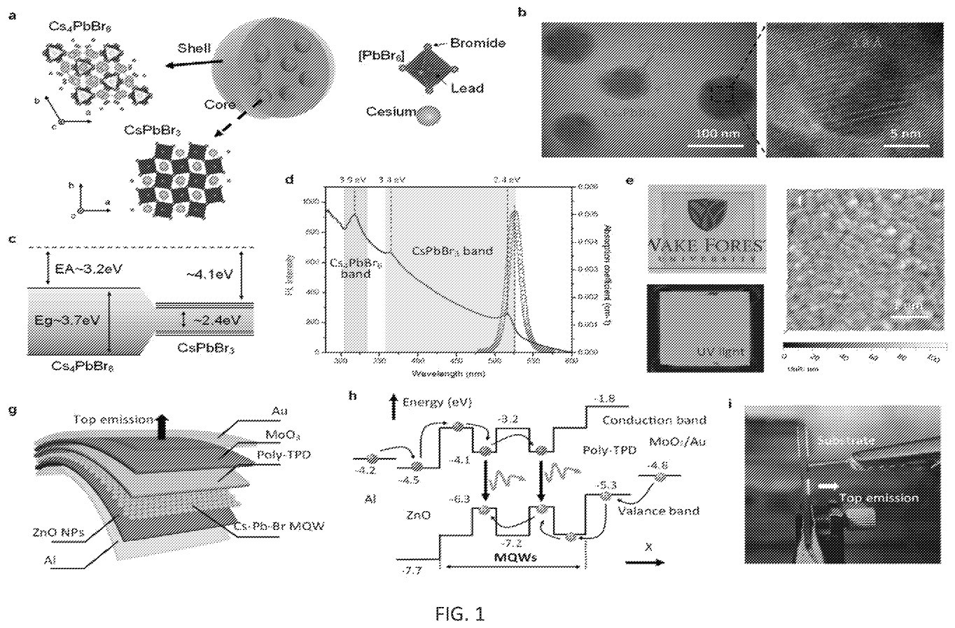

As described herein, composite nanoparticles comprise a host matrix comprising A₄BX_{6-z}Y_{z}, and ABX₃₋ₚYₚ inclusions dispersed within the host matrix of the composite nanoparticle, wherein A is an alkali metal, B is an element selected from the group consisting of transition metals, Group IVA elements and rare earth elements and X and Y are independently selected from Group VIIA elements, 0≤z≤6, and 0≤p<3. In some embodiments, the host matrix and inclusions present a core shell architecture. In the present example, CsPbBr₃ nano-inclusions embedded Cs₄PbBr₆ matrix, is illustrated in FIG. 1a. The core-shell pervoskite films were fabricated from solutions made by dissolving PbBr₂ and CsBr in dimethyl sulfoxide (DMSO) at molar ratios of 1:1.5 without additive. Films were spun on glass substrates at room temperature in a nitrogen-filled glovebox. The formation of Cs—Pb—Br core-shell perovskites was initiated by dripping acetone for fast crystallization during spin-coating followed by thermal post annealing for 10 min. Different with organic ligand terminated low dimensional perovskite (nanoparticles, nanowires, nanoplates, or quasi-2D), the CsPbBr₃ nanocrystals (5˜7 cores) are imbedded in Cs₄PbBr₆ host crystals, which was demonstrated by TEM microscopy as shown in FIG. 1b. The sizes of CsPbBr₃ nanoinclusions range from 10 nm to 15 nm as the Cs₄PbBr₆ shell layer is as thick as ˜20 nm. High-resolution TEM image shows the lattice spacing distances of CsPbBr₃ (100) and Cs₄PbBr₆ (100) which are 8.5 Å and 3.8 Å respectively. The (010) plane of Cs₄PbBr₆ was also observed in an angle of 60° with (100) plane. In contrast, some fringe patterns on CsPbBr₃ area were also recorded due to the overlapping the Cs₄PbBr₆ lattice. The electron affinity levels of CsPbBr₃ and Cs₄PbBr₆ were successfully estimated to 3.2 eV and 4.1 eV respectively, indicating a type I heterojunction (FIG. 1c) at the interface together with the band gaps of CsPbBr₃ (˜2.4 eV) and Cs₄PbBr₆ (˜3.7 eV) confirmed by the absorption edges in FIG. 1d. The CsPbBr₃—Cs₄PbBr₆ composite showed an emission peak at 520 nm which aligns with the intrinsic CsPbBr₃ fluorescence.

The CsPbBr₃—Cs₄PbBr₆ thin film on glass substrate was clear with yellow tint in room light (FIG. 1e) and showed a strong green luminescence (520 nm, FWHM 20 nm) with UV excitation. AFM image in FIG. if indicates the compact and smooth film morphology with an RMS roughness of 3.94±0.52 nm. The CsPbBr₃—Cs₄PbBr₆ pervoskite thin film exhibited a QY as high as 20% and maintained 90% of the value for 9 month in ambient storage. The high quality and stability of the CsPbBr₃—Cs₄PbBr₆ thin films enabled the development of multi-layer devices. The LED architecture [Al (60 nm)/ZnO (35 nm)/CsPbBr₃—Cs₄PbBr₆ (100 nm)/Poly-TPD (60 nm)/MoO3 (9 nm)/Au (15 nm)] chosen for this example is shown in FIG. 1g. The device operates via direct radiative e-h pair formation within the CsPbBr₃—Cs₄PbBr₆ multi quantum wells (MQWs) by injecting charge carriers from neighboring charge transport layers (CTLs) as depicted in FIG. 1h. The emitted photons were out-coupled from the semi-transparent top Au electrode as demonstrated in FIG. 1i.

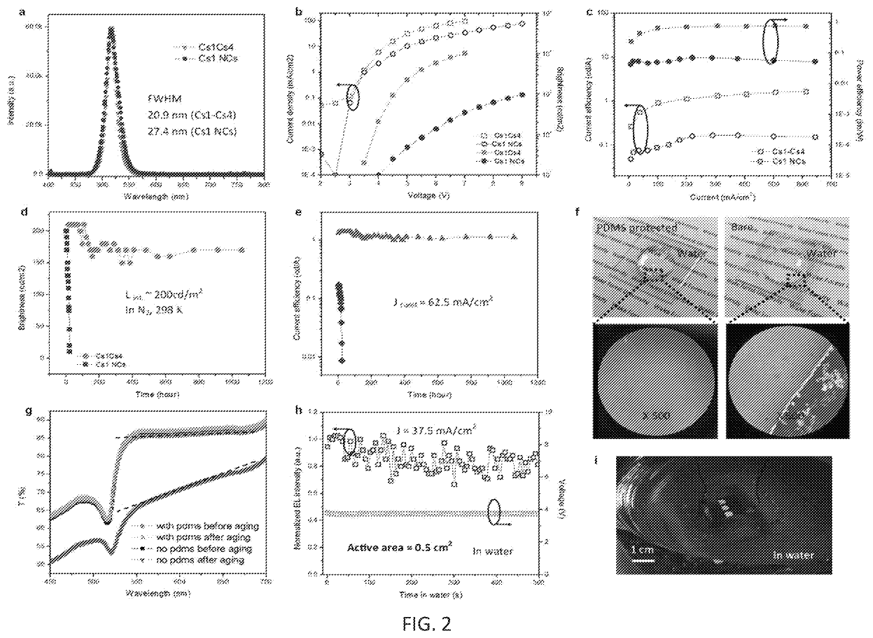

The CsPbBr₃—Cs₄PbBr₆ device showed an electroluminescence (EL) peak with the full width of half maximum (FWHM) of 20.9 nm solely from the imbedded CsPbBr₃ nanoinclusions, which was sharper than the emission from CsPbBr₃ NC device (FWHM=27.4 nm, FIG. 2a). The uniformity of CsPbBr₃ NC size was attributed to the broad emission peak. Regardless of the emitter structure, the both of devices showed typical diode behavior. However, the CsPbBr₃—Cs₄PbBr₆ device showed a turn-on voltage of 3.5 V close to the optical bandgap of Cs₄PbBr₆ indicating that the shell played a role of buffer layer to take over the charge injection into potential wells. At the same voltages, the brightness of the CsPbBr₃—Cs₄PbBr₆ device (10,070 cd/m2) was improved by two orders of magnitude comparing to the CsPbBr₃ NC device which led to a tenfold increase in current efficiency and power efficiency (1.64 cd/A and 0.77 lm/W). It was also found the CsPbBr₃ NC device showed a higher break-down voltage up to 9 V. For the sake of date reproducibility and validity, the device measurements were conducted in on-off alternative mode (2 second for each acquisition) and averaged from 0.16 cm² pixel by a CCD luminance meter. More importantly, operation stability was dramatically improved in CsPbBr₃—Cs₄PbBr₆ device. Under a constant current density (62.5 mA/cm2), 90% of the initial brightness (200 cd/m2) and current efficiency (1.4 cd/A) were maintained over 1000 hours in N₂ glovebox. In contrast, the CsPbBr₃ NC device showed a quick degradation to 10% in 20 hours.

Even though the solid cap significantly improved the device lifetime, the Cs₄PbBr₆ lattice was not chemically stable directly contacting water. As shown in FIG. 2f, the CsPbBr₃—Cs₄PbBr₆ film was dissolved and significantly damaged in the presence of water. To further isolate H2O, the devices were finished with hydrophobic PDMS coating. Similarly, moisture is prone to change the microscopic morphology of CsPbBr₃—Cs₄PbBr₆ thin film leading to higher roughness and less coverage (Supplementary Figure S3) which reduced the transparency due to light scattering (FIG. 2g). However, optical changes were trivial with the PDMS coating. With sealed electrodes, the device could survive under the water for 500 s in FIG. 2h. Three devices were electrically connected in parallel (active area ˜0.48 cm²) for the water resistance demonstration in FIG. 2i.

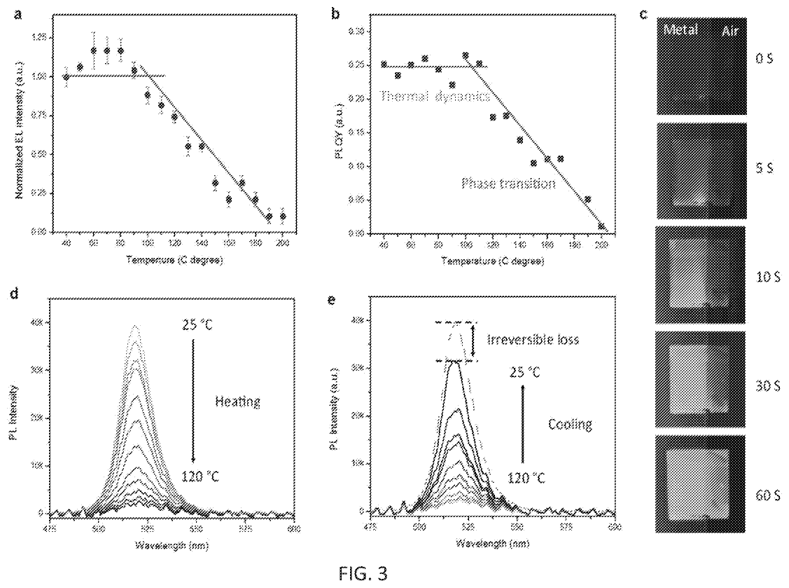

To investigate the thermal robustness, a CsPbBr₃—Cs₄PbBr₆ device was heated and maintained for 30 s. Due to the half micrometer of the total device thickness, the heat could spread over the sample in a short period of time. The devices were then cooled back to 25° C. (room temperature) before the luminous and electrical measurements. As shown in FIG. 3a, the device showed no clear sign of brightness reduction when the temperature was below 100° C., which indicates the EL could be fully recovered from the heat impact. However, the brightness decreased linearly with temperature as the annealing went over 100° C. to 200° C. A single layer of CsPbBr₃—Cs₄PbBr₆ emitter was fabricated on glass substrate and put in a further investigation. The QY of the CsPbBr₃—Cs₄PbBr₆ film was subsequently measured with post-treated temperature ascending from 40° C. to 200° C. and the results are shown in FIG. 3b. Similarly, a relative constant QY (˜25%) was achieved while the heat cycles were conducted below 100° C. This QY recoverability was attributed by the promoted dissociation of e-h pairs in CsPbBr₃ lattice with extra thermal energy, which can be visualized by cooling the preheated sample on an edge of a steel table in FIG. 3c. Since metal has a higher thermal conductivity, the steel contact half of the sample showed a faster PL recovery than the half in the air. Above 100° C., the QY reduced linearly with annealing temperature and was gradually losing its recoverability blamed to perovskite crystalline phase transition or decomposition. The PL spectra at real-time temperatures were useful to understand the contributions from the phase change (permanent decay) and the e-h pair dissociation (reversible decay). In FIG. 3d, the CsPbBr₃'s 520 nm emission peak was diminishing as the heating temperature was tuned to 120° C. The PL intensity recovered partially in FIG. 3e when the sample was cooling back down to 25° C. The reversible portion thanks to the promoted e-h dissociation probability with more thermal energy at high temperature. The PL loss is rationalized by CsPbBr₃—Cs₄PbBr₆ composition change confirmed by XRD data.

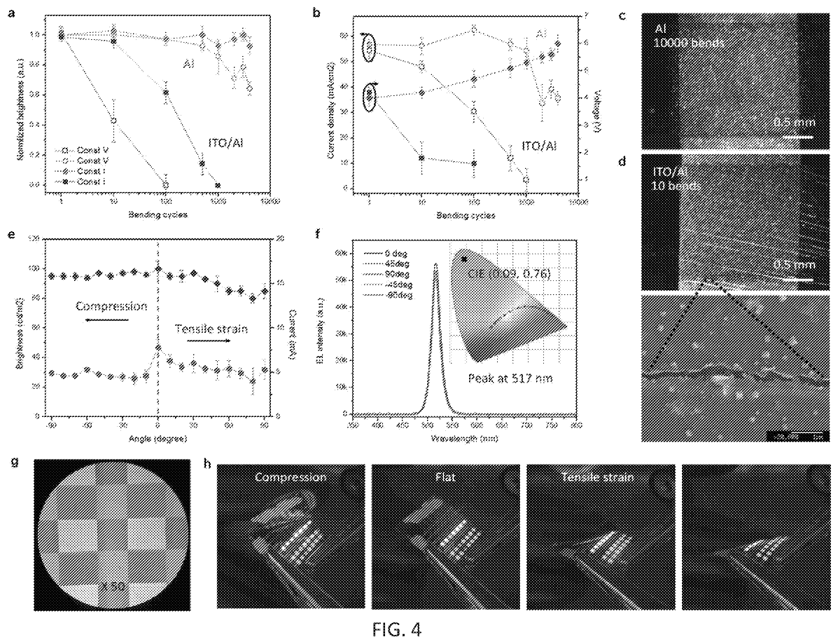

Instead of rigid glass, the flexible PET was also used as substrate to build the CsPbBr₃—Cs₄PbBr₆ LED. Device flexibility on plain and ITO coated PET substrates was investigated. In the irrigative bending tests with a constant current (62.5 mA/cm²), the ITO free device maintained over 90% of the initial brightness (70 cd/m²) up to 4,000 bending cycles as shown in FIG. 4a. The good flexibility is owing to the good ductility of the Al and Au electrodes. In contrast, 55% of the initial brightness was sacrificed within only 10 bends on ITO coat PET substrate and the device was died within 100 bends. This directly resulted from the significant decay of the voltage (FIG. 4b) due to the current leakage through the deep cracks initiated by the bottom ITO. The morphology of ITO-free device barely changed even after 10,000 bending cycles (FIG. 4c) while destructive ITO damages were created with only 10 bends and ripped the other function layers in FIG. 4d. FIG. 4e shows the luminance and current variation as a function of bending angle which ranges from −90° (compression) to +90° (tensile strain). The device exhibited stable luminescent output (100±5 cd/m2 at 0°, 95±2 cd/m2 at −90°, 85±5 cd/m2 at +90°) and current flow (48.75±5.63 mA/cm2 at 0°, 30.62±1.88 mA/cm2 at −90°, 33.13±6.88 mA/cm2 at +90°). The EL spectra (FIG. 4f) also remained intact and stable in the different bending positions. For demonstration, an 8×8 CsPbBr₃—Cs₄PbBr₆ LED dot matrix was developed by patterning the bottom Al and top Au electrodes. Each display pixel was controlled to 1×1 mm² (FIG. 4g). The pixel rows were selectively illuminated in different bending positions with no significant brightness change as shown in FIG. 4h.

The ligand assisted CsPbBr₃ nanocrystals have a good stability in liquid suspension. However, once the nanocrystals are processed into the thin film, it suffers the stability issue and the surface agents become unwanted. There are three reasons: (1) The remained surface agents are normally sensitive to air not as stable as in solution. The instability of nanocrystal emitter in solid form is one of the major problems leading to the short lifetime of EL device. The loss of surface ligands could also cause the nanocrystals fusion or phase transition, which ultimately have negative impacts on radiative efficiency. (2) The excessive organic ligands in chemical synthesis make it difficult to dry the film because of the strong bonds between solvent molecules and the surface agents. The bottom “wet” film is a major issue for the deposition of top functional layer. (3) The organic ligands normally have high resistivity which increase the barrier for carrier injection to emitter under electric field. The consequences are higher driving voltage and low power efficiency which accelerate the device degradation.

The Cs₄PbBr₆ solid capping is an efficient and facile method to stabilize CsPbBr₃ nanocrystals without additives. Unlike fuzzy organic ligands, the Cs₄PbBr₆ shell was demonstrated to be thick and compact which seals the CsPbBr₃ nanocrystals air tight. There is barely moisture and air penetrations into the emission centers which significantly improved stability of CsPbBr₃—Cs₄PbBr₆ system. Crystalized by anti-solvent or/and thermal annealing. The CsPbBr₃—Cs₄PbBr₆ thin film is hard and flat in terms of morphology which eases the deposition of top layers. The solvent annealing is also a low temperature process which enables the devices on flexible plastic substrates. Meanwhile, the solid Cs₄PbBr₆ shell acts as a mechanical shield to reduce the friction between CsPbBr₃ nanocrystals in distortional substrates. The type I heterojunction at the CsPbBr₃—Cs₄PbBr₆ interface constructs a quantum well for the efficient exciton radiative recombination. Unlike carrier tunneling through organic ligands, the e-h pairs are formed in Cs₄PbBr₆ (˜3.7 eV) and transferred to CsPbBr₃ (˜2.4 eV). The e-h pairs are trapped in CsPbBr₃ confinement, then recombine leading to the photon emission. However, more works are required to carry out for a deep understanding of the energy transfer mechanism in the heterojunction to further improve the CsPbBr₃—Cs₄PbBr₆ LEDs' quantum efficiency.

Top-emitting structure of thin film LEDs allows driving transistors implemented under the LEDs, facilitating display contrast as well as its compatibility with the active driving circuits. Furthermore, due to the metal electrode replacing ITO, the top-emitting structure used dual metal electrodes which has a significantly improvement on the stabilities such as luminance, emission efficiency, and color accuracy.

Since OLED technology was first commercialized in 1997 by Tohoku Pioneer, the OLED display market has been well developed in the past two decades and is expected to garner $37.2 billion by 2020. However, the cost of OLED technology is still higher than its competitors such as LCD display. One of the main holds is the cost of high-purity, efficient, and stable organic semiconductors that require extremely high standard synthetic conditions and purification processes. For instant, the green emissive pi-conjugated materials are costly about 10 USD per m² in an industrial scale comparing to 0.6 USD per m² of Cs—Pb—Br materials. Regardless, the Cs—Pb—Br perovskite LED provides a dramatic high color purity that the organic semiconductor cannot compete. Even comparing with the state-of-the-art CdSe or InP quantum dots, the Cs—Pb—Br perovskite shows narrower FWHM and low cost, more importantly the ease of in-situ preparation. Nonetheless, typical type-I CdSe or InP QDs with rather thin (1-2 nm) shells are susceptible to becoming charged in actual devices, particularly at high current densities, resulting in substantial efficiency decrease and poor device stabilities.

Materials and Methods

### Preparation of Cs—Pb—Br Precursor Solution

Cs—Pb—Br precursor was prepared by adding PbBr₂ and CsBr in 5 ml vials with the molar ratio of 1:1.5 into Dimethyl sulfoxide (DMSO). The mixture was stirred for 2 hours at 65° C. until completely dissolved.

### Cs—Pb—Br Thin Film Fabrication

The Cs—Pb—Br precursor solution was spin-coated onto the substrates in N₂ filled glove box. The spin speed was accelerated to final speed of 4000 rpm through 1000 rpm in 3 seconds. A wet layer of Cs—Pb—Br perovskite is formed in the first 30 second. Then, two droplets of anti-solvent acetone was applied on the top of the spinning substrates to create a fast crystallization for CsPbBr₃—Cs₄PbBr₆ formation. The duration of the entire spinning coat process is 60 seconds. For devices on glass, the samples were heated to 250° C. for 10 mins to improve the crystallization. For devices on PET substrate, 75° C. was used in post annealing to remove solvent residue.

### Photoluminescence Quantum Yield (PLQY)

An integrating sphere was employed to determine the quantum yield (QY) of perovskite samples. The sample was added in a thin cuvette and was excited with a 405 nm blue LED light. The scattered excitation, along with emission, were collected by using a fiber optic coupled spectrometer (FLAME-S-XR1-ES). The whole spectrum was collected for both a reference (cuvette with DMSO only) and for the sample.

The ratio of the number of emission photons over the number of absorbed photons was used to determine the QY as shown in the equation below,

$$QY = \frac{{S}_{e m} - {R}_{e m}}{{R}_{e x c} - {S}_{e x c}}$$

where Sem and Sexc are the integrated signal in the emission and excitation region, respectively, for the sample, and Rem and Rexc are the integrated signal in the emission and excitation region, respectively, for the reference. As a check for the accuracy of the system, the QY of Rhodamine 6G in ethanol was found to be 94.4%, close to the literature value of 95%. (Kubin, R. F.; Fletcher, A. N. Fluorescence quantum yields of some rhodamine dyes. J Lumin. 1982, 27, 455-462.)

### X-Ray Powder Diffraction (XRD)

The crystalline phase analysis was performed by an X-ray powder diffractometer (Bruker D2 PHASER) in ambient.

### Steady-State Photoluminescence (PL) Measurement

The PL of Cs—Pb—Br perovkite layers in different molar ratio was measured by a spectrofluorometer (PerkinElmer LS50B) on glass substrates.

### Scanning Electron Microscopy (SEM)

A scanning electron microscope (JEOL 6330) was utilized to analyze the morphology of different molar ratio thin films and CsPbBr₃ and Cs₄PbBr₆ microcrystals.

### Transmission Electron Microscopy (TEM)

TEM images of Cs₄PbBr₆ nanograins were taken on a JEOL JEM-1200EX. CsPbBr₃ and Cs₄PbBr₆ nanograins thin film was peeled off by a blade and placed on copper grid as imaging sample. The selected area electron diffraction patterns were achieved as well.

### High-Resolution Transmission Electron Microscopy (HR-TEM)

HT-TEM measurements were performed on an aberration-corrected FEI Titan S 80-300 STEM/TEM microscope equipped with a Gatan OneView camera at an acceleration voltage of 300 kV.

### LED Fabrication

Devices were built on a 2.54 cm×2.54 cm plain glass substrate. The glass substrates are cleaned in an ultrasonic bath with acetone followed by methanol and isopropanol for 1 hour each. A 100 nm thick layer of Al was pre-coated by thermal evaporator as bottom reflective electrode. The substrates were dry-cleaned for 30 min by exposure to an UV-ozone ambient. ZnO nanoparticle suspensions (˜35 nm) were spin-coated onto the Al-coated glass substrates at 4000 rpm for 30 s and baked at 100° C. for 30 min in vacuum oven. The substrates were transferred into glove box for further depositions. CsPbBr₄—Cs₄PbBr₆ perovskite layers were deposited by spin-coating at 4000 rpm for 60 s from 1:1.5 PbBr₂-to-CsBr precursor solution. Poly-TPD chlorobenzene solutions (concentration: 10 mg/mL) at 2000 rpm for 30 s were applied for hole transport layer. After baking, MoO3 (9 nm) and Au semi-transparent electrode (15 nm) were deposited using a thermal evaporation system through a shadow mask under a vacuum of 2×10⁻⁷ Torr.

### LED Characterization

The LED devices in this report are measured in on-off mode inside of glove box at room temperature (25° C.) without encapsulation. Current versus voltage characteristics were measured using a Keithley 2400 source measure unit. Simultaneously, luminance (in cd/m²) was directly measured using a photometer (ILT 1400-A) with an optical fiber facing light-emitting pixel. The EL spectra for the devices were collected by an ILT 950 spectroradiometer (International Light Technologies).

TABLE VI
Materials employed in the Examples

| Abbreviation | Chemical name | Supplier |
|---|---|---|
| CsBr | Cesium bromide | Sigma-Aldrich |
| PbBr₂ | Lead bromide | Strem chemicals |
| DMOS | Dimethyl sulfoxide | VWR International |
| Poly-TPD | Poly(4-butylphenyl- | American Dye |
| | diphenyl-amine) | Source |
| ZnO | | |

Various embodiments of the invention have been described in fulfillment of the various objectives of the invention. It should be recognized that these embodiments are merely illustrative of the principles of the present invention. Numerous modifications and adaptations thereof will be readily apparent to those skilled in the art without departing from the spirit and scope of the invention.

1. A composite nanoparticle comprising:
a host matrix comprising A₄BX_{6-z}Y_{z}; and
ABX₃₋ₚYₚ inclusions dispersed within the host matrix of the composite nanoparticle, wherein A is an alkali metal, B is an element selected from the group consisting of transition metals, Group IVA elements and rare earth elements and X and Y are independently selected from Group VIIA elements, 0≤z≤6, and 0≤p<3.

2. The composite nanoparticle of claim 1, having a diameter of at least 100 nm.

3. The composite nanoparticle of claim 1, having a diameter of 100 nm to 500 nm.

4. The composite nanoparticle of claim 1, wherein the ABX₃₋ₚYₚ inclusions are dispersed in the host matrix bulk.

5. The composite nanoparticle of claim 1, wherein the ABX₃₋ₚYₚ inclusions are photoluminescent and/or electroluminescent.

6. The composite nanoparticle of claim 5, wherein the ABX₃₋ₚYₚ inclusions emit light in the visible region of the electromagnetic spectrum.

7. The composite nanoparticle of claim 5, wherein the ABX₃₋ₚYₚ inclusions have an emission full width half maximum of 20 nm or less.

8. The composite nanoparticle of claim 1, wherein ABX₃₋ₚYₚ inclusions have a size of 10 nm to 20 nm.

9. The composite nanoparticle of claim 1, wherein A is Cs and B is Pb.

10. The composite nanoparticle of claim 9, wherein X is Br or I and z and p are each 0.

11. The composite nanoparticle of claim 10, wherein the host matrix comprises Cs₄PbBr₆ and the inclusions are CsPbBr₃.

12. The composite nanoparticle of claim 10, wherein the host matrix comprises Cs₄PbBr₆ and the inclusions are CsPbI₃.

13. The composite nanoparticle of claim 9, wherein X is I, Y is Br, p=1 and z=6.

14. The composite nanoparticle claim 13, wherein the host matrix comprises Cs₄PbBr₆ and inclusions are CsPbI₂Br.

15. The composite nanoparticle of claim 1, wherein the ABX₃₋ₚYₚ inclusions are crystalline.

16. The composite nanoparticle of claim 1, wherein the ABX₃₋ₚYₚ inclusions establish a Type I band offset with the A₄BX_{6-z}Y_{z} host matrix.

17. The composite nanoparticle of claim 1, wherein a capping layer resides between the ABX₃₋ₚYₚ inclusions and the A₄BX_{6-z}Y_{z} host matrix.

18. The thin film of claim 17, wherein the capping layer has composition different from the ABX₃₋ₚYₚ inclusions and the A₄BX_{6-z}Y_{z} host matrix.

19. The thin film of claim 18, wherein the capping layer exhibits a Br gradient.

20. An thin film comprising:
a continuous host matrix comprising A₄BX_{6-z}Y_{z}; and
ABX₃₋ₚYₚ inclusions dispersed within the continuous host matrix, wherein A is an alkali metal, B is an element selected from the group consisting of transition metals, Group IVA elements and rare earth elements and X and Y are independently selected from Group VIIA elements, 0≤z≤6, and 0≤p<3.

21. The thin film of claim 20, wherein the ABX₃₋ₚYₚ inclusions are dispersed in the host matrix bulk.

22. The thin film of claim 20, wherein the ABX₃₋ₚYₚ inclusions are photoluminescent and/or electroluminescent.

23. The thin film of claim 20, wherein the ABX₃₋ₚYₚ inclusions emit light in the visible region of the electromagnetic spectrum.

24. The thin film of claim 23, wherein the ABX₃₋ₚYₚ inclusions have an emission full width half maximum of 20 nm or less.

25. The thin film of claim 20, wherein ABX₃₋ₚYₚ inclusions have a size of 10 nm to 20 nm.

26-37. (canceled)

38. An electroluminescent device comprising:
a first electrode and a second electrode; and
a light emitting layer positioned between the first and second electrodes, the light emitting layer comprising a continuous host matrix comprising A₄BX_{6-z}Y_{z} and ABX₃₋ₚYₚ inclusions dispersed within the host matrix, wherein A is an alkali metal, B is an element selected from the group consisting of transition metals, Group IVA elements and rare earth elements and X and Y are independently selected from Group VIIA elements, 0≤z≤6, and 0≤p<3.

39. The electroluminescent device of claim 38, wherein the ABX₃₋ₚYₚ inclusions are dispersed within the host matrix bulk.

40. The electroluminescent device of claim 38, wherein the ABX₃₋ₚYₚ inclusions emit light in the visible region of the electromagnetic spectrum.

41. The electroluminescent device of claim 40, wherein the ABX₃₋ₚYₚ inclusions have an emission full width half maximum of 20 nm or less.

42. The electroluminescent device of claim 38, wherein ABX₃₋ₚYₚ inclusions have a size of 10 nm to 20 nm.

43-62. (canceled)
